(19) United States
(12) Patent Application Publication
(10) Pub. No.: US 2012/0168210 A1
(43) Pub. Date: Jul. 5, 2012

(54) Methods and Structures Involving Terminal Connections

(75) Inventors: Terence B. Hook, Jericho, VT (US); Vidhya Ramachandran, Ossining, NY (US)

(73) Assignee: INTERNATIONAL BUSINESS MACHINES CORPORATION, Armonk, NY (US)

(21) Appl. No.: 12/984,640

(22) Filed: Jan. 5, 2011

(51) Int. Cl. H05K 1/09; G03F 7/20

(52) U.S. Cl. 174/257; 430/314

(57) ABSTRACT

A method for forming a conductive contact includes forming a copper contact region in an intermediary layer, depositing an insulator layer over the copper contact region and the intermediary layer, patterning a photoresist layer on the insulator layer, etching to remove a portion of the insulator layer and expose a portion of the copper contact region, depositing a conductive material layer over the exposed portion of the copper contact region and the photoresist layer, and removing the photoresist layer and the conductive material layer disposed on the photoresist layer.

### BACKGROUND

The present invention relates to silicon device fabrication methods, and more specifically, to forming terminal connections in silicon devices.

The use of copper material as a conductor in silicon devices has a number of advantages however; copper often exhibits poor bonding qualities with other conductive materials.

The application of other metals such as, aluminum to a surface of the copper results in a surface that is conducive to forming a secure electrical and physical contact to another conductive material. For example, when an electrical connection between a copper interconnect and a lead or lead-free solder-bump terminal is desired, a layer of aluminum may be deposited on the copper to improve the effectiveness of the bond between the materials.

### BRIEF SUMMARY

According to one embodiment of the present invention, a method for forming a conductive contact includes forming a copper contact region in an intermediary layer, depositing an insulator layer over the copper contact region and the intermediary layer, patterning a photoresist layer on the insulator layer, etching to remove a portion of the insulator layer and expose a portion of the copper contact region, depositing a conductive material layer over the exposed portion of the copper contact region and the photoresist layer, and removing the photoresist layer and the conductive material layer disposed on the photoresist layer.

According to another embodiment of the present invention, a conductive contact arrangement includes a substrate, an intermediary layer, a copper contact region disposed in the intermediary layer, an insulator layer, a cavity defined by the insulator layer and the copper contact region, and a conductive material layer disposed in the cavity.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIGS. 1-6 illustrate a method for forming a conductive contact region, in which:

FIG. 1 illustrates a side view of a portion of a silicon device;

FIG. 2 illustrates the formation of a photoresist material;

FIG. 3 illustrates the resultant structure following an etching process;

FIG. 4 illustrates the resultant photoresist following an etching process;

FIG. 5 illustrates the resultant structure following the deposition of a conductive material; and

FIG. 6 illustrates the resultant structure following the removal of the photoresist.

FIGS. 7-9 illustrate an alternative embodiment of a method for forming a conductive contact region, in which:

FIG. 7 illustrates an etching process that removes a portion of the insulator layer;

FIG. 8 illustrates the deposition of the conductive material; and

FIG. 9 illustrates the resultant structure following the removal of the photoresist material.

FIGS. 10-12 illustrate yet another alternative embodiment of a method for forming a conductive contact region, in which:

FIG. 10 illustrates the photoresist material and the removal of portions of the insulator layers;

FIG. 11 illustrates the deposition of the conductive material; and

FIG. 12 illustrates the resultant structure following the removal of the photoresist material.

FIG. 13 further illustrates a method for removing the photoresist material.

### DETAILED DESCRIPTION

Previous methods for forming an electrical connection to a copper portion of a silicon device included a number of patterning, etching, and pattern removal steps. The methods described below and the resultant structures offer a more efficient process for forming an electrical connection.

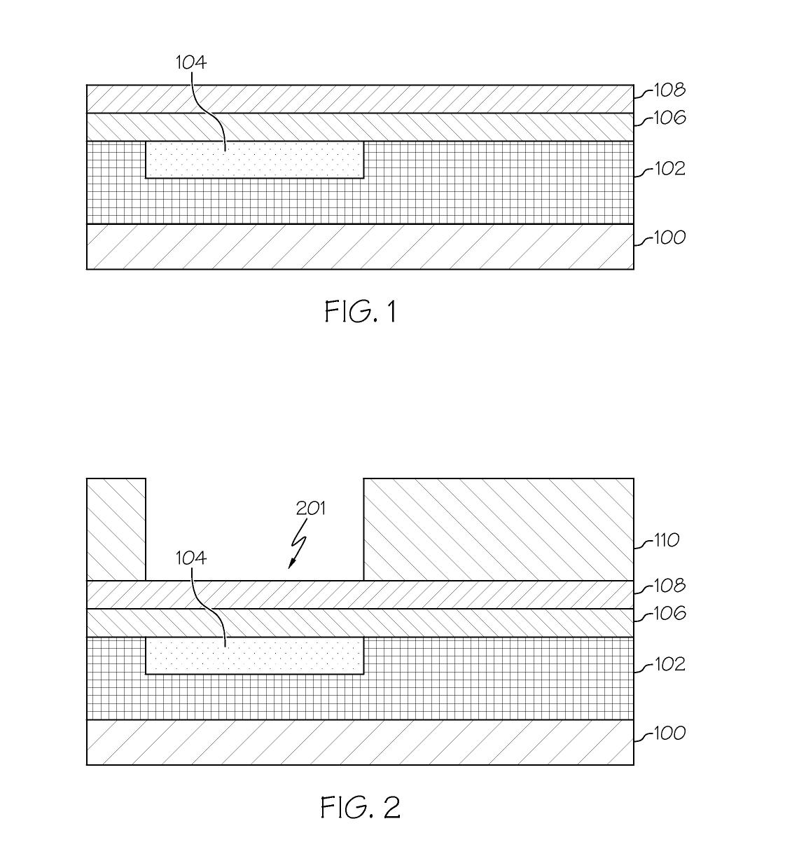

FIGS. 1-6 illustrate a method for forming a conductive contact region using a single lithographic patterning step. In this regard, with reference now to FIG. 1, a side view of a portion of a silicon device is shown that includes a silicon substrate 100, an intermediary layer 102 disposed on the substrate 100 that may include, for example, a dielectric, or insulating material. A copper pad region 104 is formed in the intermediary layer 102. The copper pad region 104 may be formed by, for example, a deposition process such as, a chemical vapor deposition (CVD), and a lithographic patterning and etching process. Insulator layers 106 and 108 are disposed on the intermediary layer 102 and the copper pad region 104. The insulator layers 106 and 108 in the illustrated embodiment include a nitride material and an oxide material respectively.

FIG. 2 illustrates the formation of a photoresist material 110 formed by a lithographic patterning process that defines an exposed region 201 of the insulator layer 108.

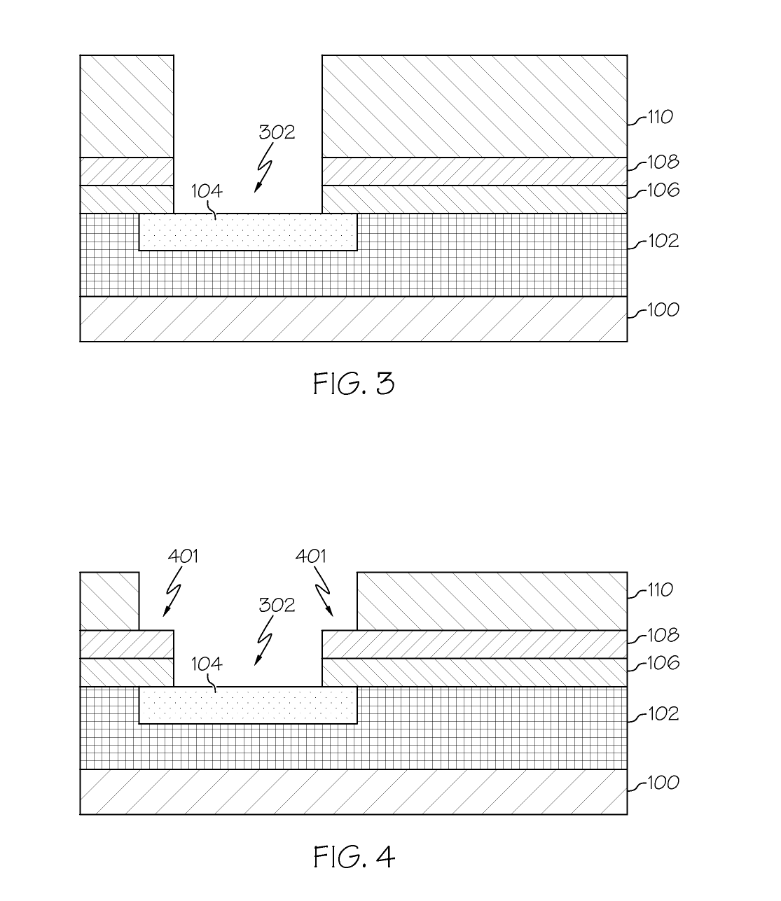

FIG. 3 illustrates the resultant structure following an etching process such as, for example, a reactive ion etching (RIE) process that removes the exposed portion of the insulator layers 108 and 106 to form a cavity 302 that exposes a portion of the copper pad region 104.

FIG. 4 illustrates the resultant photoresist 110 following an isotropic etching process, such as, for example, a wet chemical etching process that removes portions of the photoresist 110 to expose a region 401 of the insulator layer 108.

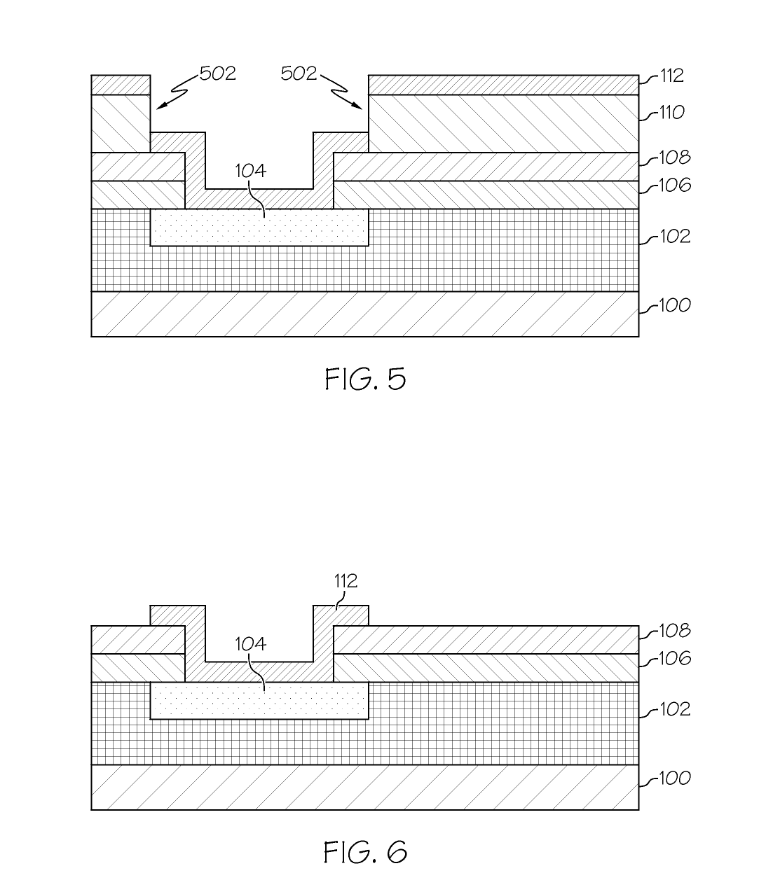

FIG. 5 illustrates the resultant structure following the deposition of a conductive material 112 such as, for example a metallic stack including aluminum over the exposed portions of the copper pad region 104, the insulator layers 108 and 106, and the photoresist 110. The conductive material 112 may be formed by a deposition process such as, for example a CVD or sputtering process. The illustrated embodiment includes an exposed region 502 of the photoresist 110 that remains unobstructed by the conductive material 112.

FIG. 6 illustrates the resultant structure following the removal of the photoresist 110 (of FIG. 5) and the conductive material 112 that was formed on the photoresist. A wet isotropic etching process that is operative to remove the photoresist material 110 contacts the photoresist material 110 in the exposed region 502. The etching of the photoresist material 110 results in the removal of the conductive material 112 that was formed over the photoresist material 110.

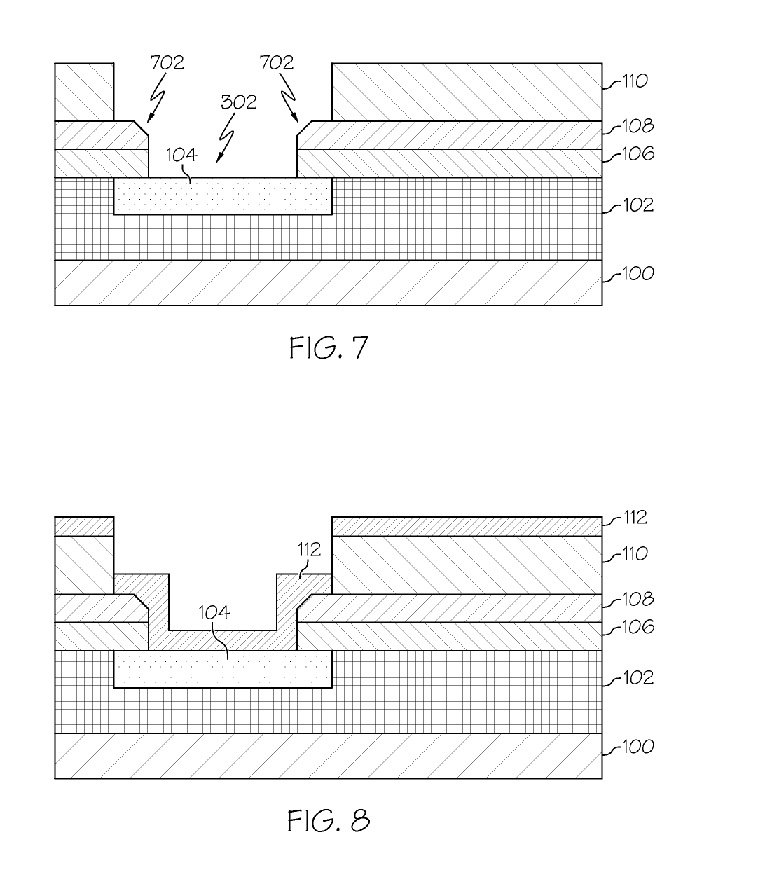

FIGS. 7-9 illustrate an alternative embodiment of a method for forming a conductive contact region. In the illustrated alternate method, the methods described above in FIGS. 1-4 are performed followed by the methods described below in FIGS. 7-9. Referring to FIG. 7, following the etching of the photoresist material 110 (as shown in FIG. 4), an etching process is performed that removes a portion of the insulator layer 108, resulting in an angled, curved, beveled, or sloped region having a surface 702.

FIG. 8 illustrates the deposition of the conductive material 112 over the exposed copper pad region 104, the insulator layer 108, and the photoresist material 110. If a non-conformal deposition process is used to deposit the conductive material 112, the conductive material 112 may not cover the vertically orientated edges of the insulator layer 108 (depending on the amount of material deposited and the thickness of the insulator layers) the angled surface 702 encourages the conductive material 112 to conform over the insulator layer 108 resulting in a continuous layer of conductive material 112 that is formed on the copper region 104 and the exposed regions of the insulator layer 108.

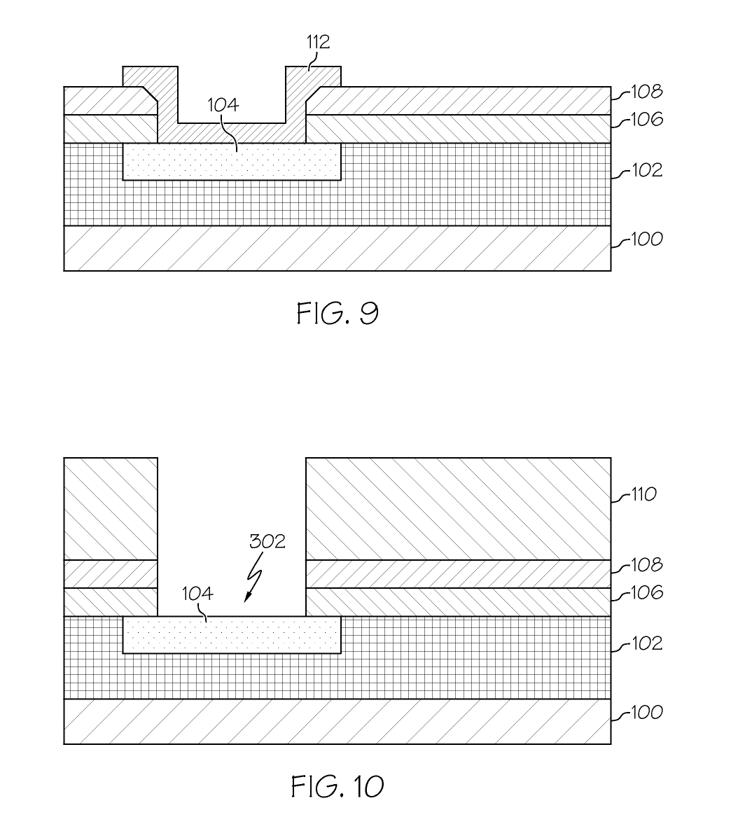

FIG. 9 illustrates the resultant structure following the removal of the photoresist material 110 (of FIG. 8) and the conductive material 112 that was formed on the photoresist material 110 using an isotropic etching process similar to the process described above.

FIGS. 10-12 illustrate another alternative embodiment of a method for forming a conductive contact region. In the illustrated alternate method, the methods described above in FIGS. 1-3 are performed followed by the methods described below in FIGS. 10 and 12. FIG. 10 illustrates the photoresist material 110 and the removal of portions of the insulator layers 106 and 108.

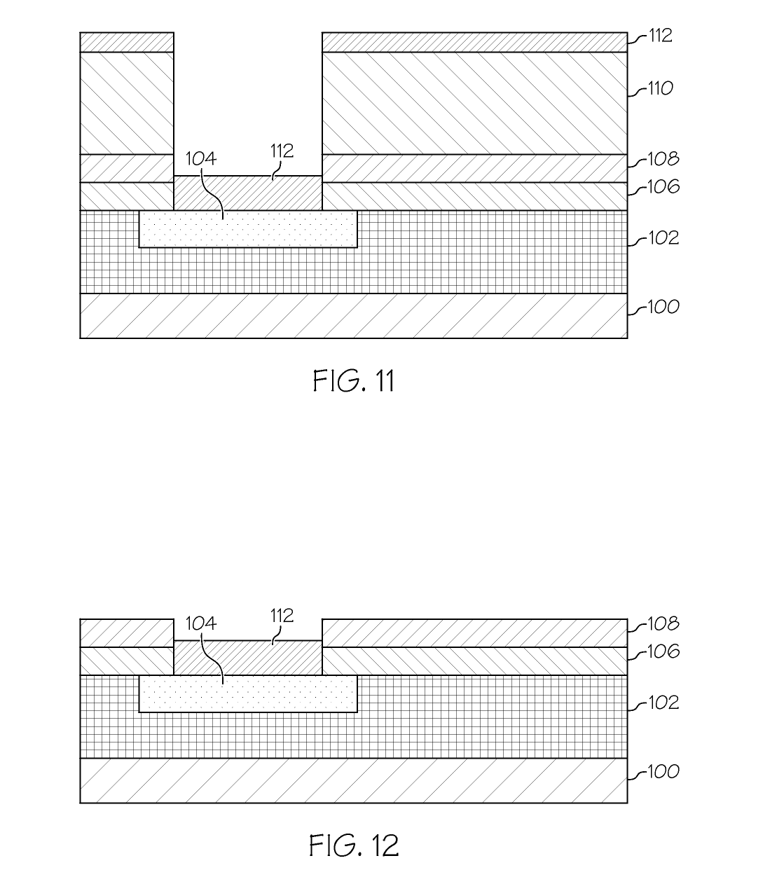

FIG. 11 illustrates the deposition of the conductive material 112 over the exposed portions of the copper pad region 104 and the photoresist material 110.

FIG. 12 illustrates the resultant structure following the removal of the photoresist material 110 and the conductive material 112 that was deposited on the photoresist material 110 using an isotropic etching process similar to the methods described above.

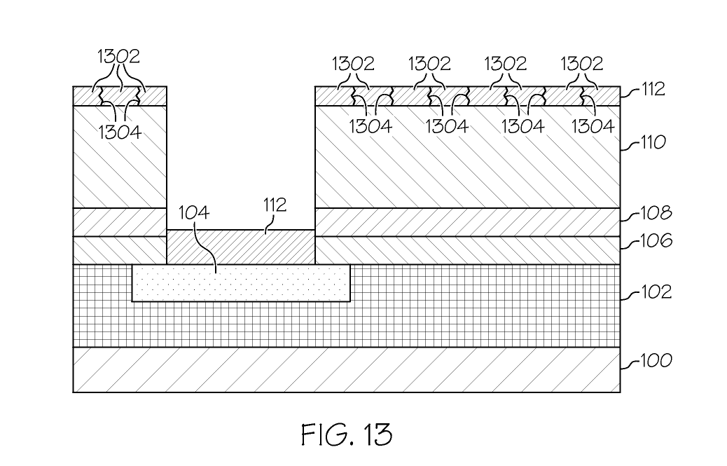

FIG. 13 illustrates a method for removing the photoresist material that may be used in any of the methods described above. In this regard, the arrangement is cooled to approximately room temperature following the deposition of the conductive material 112. The difference in thermal diffusivity between the photoresist material 110 and the conductive material 112 cause different rates of contraction of the materials as the arrangement is cooled. The different rates of contraction cause the conductive material 112 layer to break into pieces 1302 that are defined by cracks 1304. An isotropic etching process is used to remove the photoresist material 110 and the pieces 1302 of the conductive material 112. The isotropic etching process is improved by allowing etchant chemicals to contact the photoresist material 110 by passing through the cracks 1304. The cracks 1304 reduce the integrity of the conductive material 112, further easing the removal of the conductive material 112.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A method for forming a conductive contact, the method including:
forming a copper contact region in an intermediary layer;
depositing an insulator layer over the copper contact region and the intermediary layer;
patterning a photoresist layer on the insulator layer;
etching to remove a portion of the insulator layer and expose a portion of the copper contact region;
depositing a conductive material layer over the exposed portion of the copper contact region and the photoresist layer; and
removing the photoresist layer and the conductive material layer disposed on the photoresist layer.

2. The method of claim 1, wherein the method further includes removing a portion of the photoresist layer to expose a region of the insulator layer prior to depositing the conductive material layer.

3. The method of claim 2, wherein the depositing the conductive material layer includes depositing the conductive material layer over the exposed region of the insulator layer.

4. The method of claim 2, wherein the method further includes removing a portion of the insulator layer to define a beveled surface in the insulator layer.

5. The method of claim 4, wherein the depositing the conductive material layer includes depositing the conductive material layer over the exposed region of the insulator layer and the beveled surface of the insulator layer.

6. The method of claim 1, wherein the method further includes cooling the photoresist layer and the conductive material layer prior to removing the photoresist layer.

7. The method of claim 2, wherein the method further includes cooling the photoresist layer and the conductive material layer prior to removing the photoresist layer.

8. The method of claim 5, wherein the method further includes cooling the photoresist layer and the conductive material layer prior to removing the photoresist layer.

9. The method of claim 1, wherein the conductive material layer includes aluminum.

10. The method of claim 1, wherein the intermediary layer includes an oxide material.

11. The method of claim 1, wherein the insulator layer includes a layer of oxide material disposed on a layer of nitride material.

12. A conductive contact arrangement comprises:
a substrate;
an intermediary layer;
a copper contact region disposed in the intermediary layer;
an insulator layer;
a cavity defined by the insulator layer and the copper contact region; and
a conductive material layer disposed in the cavity.

13. The arrangement of claim 12, wherein the intermediary layer includes an oxide material.

14. The arrangement of claim 12, wherein the insulator layer includes a layer of nitride material disposed on the intermediary layer and a layer of oxide material disposed on the layer of nitride material.

15. The arrangement of claim 12, wherein the conductive material layer is further disposed on a portion of the insulator layer.

16. The arrangement of claim 14, wherein the conductive material layer is further disposed on a portion of layer of oxide material.

17. The arrangement of claim 12, wherein the cavity includes a beveled edge portion defined by the insulator layer.

18. The arrangement of claim 14, wherein a thickness of the conductive material layer is greater than a thickness of the layer of nitride material.

19. The arrangement of claim 12, wherein the conductive material layer includes aluminum.

20. The arrangement of claim 12, wherein the substrate includes a silicon material.
